(19) United States
(12) Patent Application Publication
(10) Pub. No.: US 2025/0297360 A1
(43) Pub. Date: Sep. 25, 2025

(54) SUBSTRATE PROCESSING METHOD

(71) Applicant: ASM IP Holding B.V., Almere (NL)

(72) Inventors: Kai Matsuhisa, Tokyo (JP); Trigagema Gama, Yamato-shi (JP); Wataru Adachi, Kawasaki-shi (JP)

(21) Appl. No.: 19/084,915

(22) Filed: Mar. 20, 2025

Related U.S. Application Data
(60) Provisional application No. 63/569,381, filed on Mar. 25, 2024.

(51) Int. Cl. C23C 16/40; C23C 16/02; C23C 16/44; C23C 16/458

(52) U.S. Cl. CPC C23C 16/401; C23C 16/02; C23C 16/4408; C23C 16/458

(57) ABSTRACT

A method of forming a film on a substrate comprises providing the substrate in a reaction chamber and forming the film on the substrate by repeating a cycle at least one time, wherein the forming the film comprises supplying a silicon source comprising an amine and a catalyst to the substrate, followed by supplying an oxygen source to the substrate while applying a first power to the reaction chamber from a power generator. The method further comprises performing a substrate treatment to the substrate before forming the film, wherein the film formed on the substrate is a silicon oxide.

### CROSS-REFERENCE TO RELATED APPLICATIONS

This application claims priority to U.S. Provisional Patent Application Ser. No. 63/569,381 filed Mar. 25, 2024 titled SUBSTRATE PROCESSING METHOD, the disclosure of which is hereby incorporated by reference in its entirety.

### FIELD OF INVENTION

The disclosure relates to a substrate processing method, more particularly, to a method of promoting a film formation and increasing a film growth rate on a substrate.

### BACKGROUND OF THE DISCLOSURE

As a line width of a semiconductor device continues to narrow, demand for forming a thin film precisely and conformally along a surface of the device structure is increasing. To that end, an Atomic Layer Deposition (hereinafter ALD) method has been widely used to form a thin film on the surface of the semiconductor device. In ALD method, a monolayer of a film is formed on the surface by a surface reaction and the process sequence is repeated. Therefore, a film is formed conformally on the surface of the semiconductor device. In addition to the conventional ALD method, a Plasma Enhanced ALD (hereinafter PEALD) method was introduced. In the PEALD method, at least one process gas is activated by a power to facilitate forming a film at low temperature.

The ALD and PEALD methods are performed based on a layer-by-layer process in which each process gas is supplied alternately and sequentially, and the process is repeated until a target thickness is achieved. In ALD and PEALD methods, however, a film growth rate is lower than that in CVD (Chemical Vapor Deposition) method, resulting in long processing time to achieve a target thickness and low throughput.

### SUMMARY OF THE DISCLOSURE

The disclosure discloses a method of forming a film, more particularly, a method of promoting a film formation and increasing a film growth rate on a substrate.

In one or more embodiments, the method of forming a film may be performed by providing the substrate in a reaction chamber and forming the film on the substrate by repeating a cycle at least one time, comprising: supplying a silicon source comprising an amine to the substrate, supplying a catalyst to the substrate, and supplying an oxygen source to the substrate while applying a first power to the reaction chamber from a power generator, wherein the film formed on the substrate may be a silicon oxide.

In one or more embodiments, the catalyst may be supplied while supplying the silicon source.

In one or more embodiments, the catalyst may comprise a nitrogen and a hydrogen.

In one or more embodiments, the catalyst may comprise at least one of NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

In one or more embodiments, a growth rate of the silicon oxide film on the substrate may be about 0.5 Å/cycle or greater.

In one or more embodiments, the growth rate of the silicon oxide film on the substrate may be about 1.0 Å/cycle or greater.

In one or more embodiments, the method of forming a film may further comprise performing a surface treatment to the substrate by supplying a treatment gas to the substrate while applying a second power to the reaction chamber from the power generator before forming the film, wherein performing the surface treatment may be repeated at least one time.

In one or more embodiments, the surface treatment is performed for about 1 second or less while applying the second power to the reaction chamber.

In one or more embodiments, the surface treatment may be performed for about 0.2 seconds or less while applying the second power to the reaction chamber.

In one or more embodiments, the treatment gas may comprise a nitrogen and a hydrogen.

In one or more embodiment, the treatment gas may comprise at least one of a mixture of N₂ and H₂, NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

In one or more embodiments, the silicon source may be at least one of trisilylamine ((SiH₃)₃N); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane(SiH₃N(iPr)₂); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄), or a mixture thereof.

In one or more embodiments, the oxygen source may comprise at least one of O₂, O₃, H₂O, N₂O and CO₂, or a mixture thereof.

In one or more embodiments, the first power may be applied with a power of between about 30 W and about 1500 W at a frequency of at least one of between about 300 kHz and about 1 MHz and between about 10 MHz and about 60 MHz.

In one or more embodiments, the second power may be applied with a power of between about 30 W and about 1500 W at a frequency of at least one of between about 300 kHz and about 1 MHz and between about 10 MHz and about 60 MHz.

In one or more embodiments, a cycle ratio of performing the surface treatment to forming the film may be between 1:1 and 1:10.

In one or more embodiments, the method of forming the film may be performed at between about 50° C. and about 600° C.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A to 1B illustrate a method of forming a film according to an embodiment of the disclosure.

FIGS. 2A to 2D illustrate a reaction mechanism according to an embodiment of FIG. 1.

FIGS. 3A to 3B illustrate a method of forming a film according to another embodiment of the disclosure.

FIGS. 4A to 4E illustrate a reaction mechanism according to an embodiment of FIG. 3.

FIG. 5 illustrates a timing graph of a method according to an embodiment of FIG. 1B.

FIG. 6 illustrates a timing graph of a method according to another embodiment of FIG. 3B.

FIG. 7 illustrates a silicon oxide film growth rate depending on the catalyst and the surface treatment.

FIGS. 8A and 8B illustrates silicon oxide film thicknesses depending on the type of precursors and using the catalyst or not in which the film is formed without a surface treatment.

FIG. 9 illustrates a silicon oxide film growth rate over the NH₃ plasma time in the substrate treatment step in which NH₃ is supplied as a treatment gas.

FIG. 10A and FIG. 10B are TEM (Transmission Electron Microscope) photos showing the silicon oxide film formed on the pattern according to an embodiment of the disclosure.

FIG. 11 illustrates a film growth rate of silicon oxide film over a process temperature according to an embodiment of the disclosure.

FIG. 12 illustrates a hardware configuration to perform a method of forming a film on a substrate according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

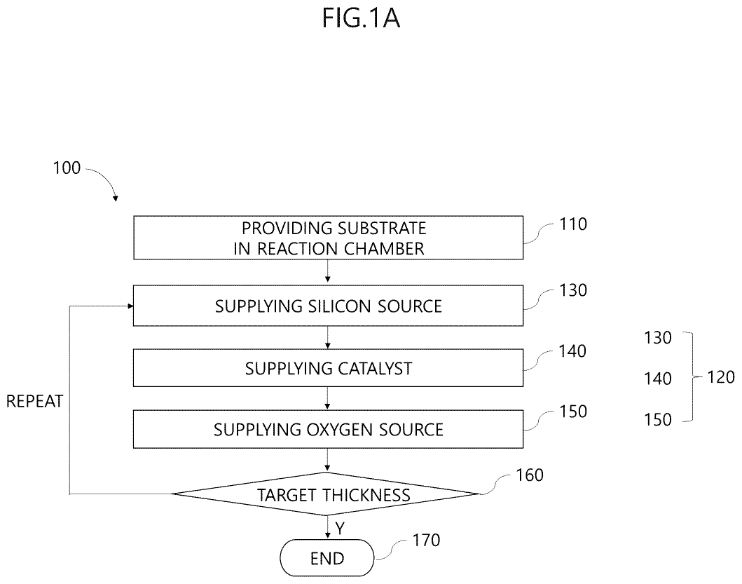

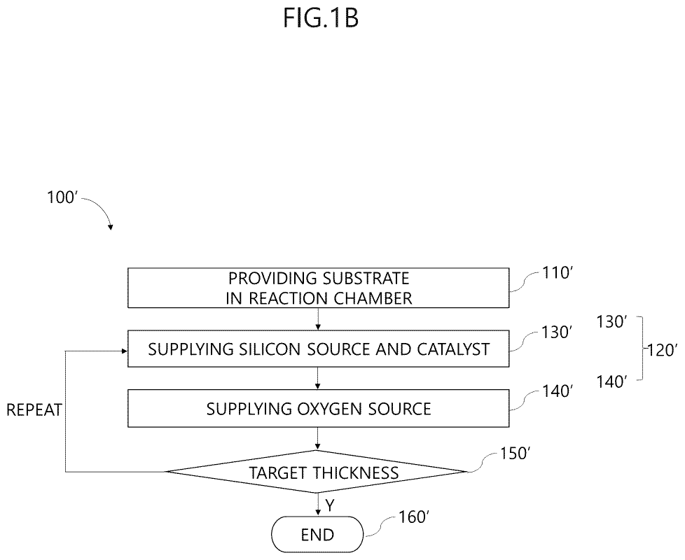

FIGS. 1A to 1B illustrate a method of forming a film according to an embodiment of the disclosure.

In a STEP 110 of the method 100 in FIG. 1A, a substrate may be provided in a reaction chamber. The substrate may comprise a non-planar structure. For instance, the non-planar structure may comprise one or more of a recess, a trench, a gap, a via, a hole, a pattern and a 3D structure. The substrate provided in the reaction chamber may be loaded onto a substrate holder installed in the reaction chamber (not shown herein). The substrate holder may comprise a susceptor and a heating block to heat up the substrate to a process temperature.

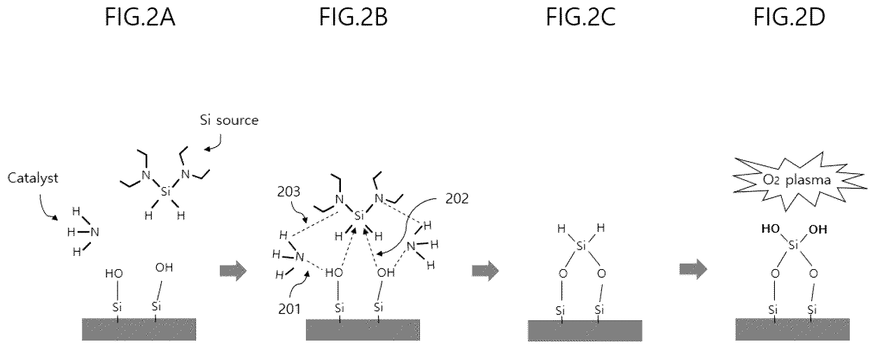

In a STEP 120 of the method 100 in FIG. 2, a film may be formed on the substrate. The film formed on the substrate may comprise silicon oxide, for example.

The STEP 120 may comprise a STEP 130 of supplying a silicon source, a STEP 140 of supplying a catalyst, and a STEP 150 of supplying an oxygen source. The STEP 120 may be performed at between about 50° C. and about 600° C. The STEPS 130, 140 and 150 may be repeated until a target film thickness is achieved.

In a STEP 160, whether the target film thickness is achieved or not may be determined. In a STEP 170, after the film target thickness is achieved, the method of forming the film may end.

In the STEP 130 and the STEP 140, the silicon source and the catalyst may be supplied to form a silicon oxide film on the substrate. The silicon source and the catalyst may be supplied sequentially and alternately.

The catalyst may promote the silicon source to react with the surface of the substrate, resulting in adsorbing thereon. In more detail, the catalyst may assist the silicon source to react with adsorption sites (e.g., OH— group) formed on the surface of the substrate, resulting in the silicon oxide film to be formed on the surface of the substrate.

In one embodiment of the disclosure, the silicon source may comprise an amine and the catalyst may comprise a nitrogen and a hydrogen.

The silicon source may comprise at least of one of trisilylamine ((SiH₃)₃N); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane (SiH₃N(iPr)₂); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄), or a mixture thereof.

The catalyst may comprise at least one of NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

In the STEP 150, an oxygen source may be supplied to the substrate. The oxygen source may react with the top surface of the silicon oxide film formed in STEPS 130 and 140, resulting in forming adsorption sites (e.g., OH— group) on the silicon oxide film. In one embodiment, the oxygen source may be supplied while applying a first power to the reaction chamber from a power generator.

The oxygen source activated by the first power may react with the top surface of the silicon oxide film more easily. The oxygen source may comprise at least one of O₂, O₃, H₂O, N₂O and CO₂, or a mixture thereof.

In the STEP 150, the first power may be at least one of a low frequency power and a high frequency power. In one embodiment, the first power may be applied with a power of between about 30 W and about 1,500 W at a frequency of at least one of between about 300 kHz and about 1 MHz and between about 10 MHz and about 60 MHz.

Optionally, the method 100 may further comprise supplying a purge gas (e.g., Ar) to the reaction chamber throughout the STEP 120.

FIG. 1B illustrates another embodiment of the disclosure. In a STEP 130′ of a method 100′, the silicon source and the catalyst may be supplied simultaneously. For instance, the catalyst may be supplied while supplying the silicon source.

In a STEP 140′ of the method 100′, an oxygen source may be supplied to the substrate. The oxygen source may react with the top surface of the silicon oxide film formed in the STEP 130′, resulting in forming adsorption sites (e.g., OH— group) on the silicon oxide film. In one embodiment, the oxygen source may be supplied while applying a first power to the reaction chamber from a power generator.

In a STEP 150′, whether the target film thickness is achieved or not may be determined. The STEP 120′ comprising the STEPS 130′ and 140′ may be repeated until a target film thickness is achieved.

In a STEP 160′, after the film target thickness is achieved, the method of forming the film may end.

FIGS. 2A to 2D illustrate a reaction mechanism according to an embodiment of FIGS. 1A to 1B.

In FIG. 2A, a silicon source and a catalyst may be supplied to the substrate on which adsorption sites (i.e., OH— group) may be formed. The silicon source may comprise an amine (e.g., aminosilane) and the catalyst may comprise a nitrogen and a hydrogen (e.g., NH₃).

In FIG. 2B, the catalyst may assist a reaction between the silicon source and the adsorption sites. The catalyst may have an unshared electron pair. For example, the nitrogen of the catalyst may contain an unshared electron pair (i.e., two unshared electrons). The polarity of unshared electron pair may cause the hydrogen comprising the adsorption site to gravitate to the nitrogen of the catalyst, resulting in the hydrogen detaching from the adsorption site (denoted as 201) while the oxygen may remain.

In this reaction, the catalyst may act as an electron donor, and therefore, may be referred to as a Lewis base. The catalyst may promote the adsorption of the silicon source on the adsorption sites (e.g., OH— group). The remaining oxygen may bond with the silicon of the silicon source (denoted as 202), forming a Si—O—Si bonding structure as illustrated in FIG. 2C.

In FIG. 2B, on the other hand, another hydrogen atom of the catalyst may react with the amine group (denoted as 203) and be removed to form a gaseous byproduct (e.g., H-amine compound), As a result, the catalyst and the amine may be removed as byproducts.

In FIG. 2D, an oxygen source may be supplied to the substrate. The oxygen source may be supplied while applying a first power to the reaction chamber. Oxygen radicals may react with the surface of the substrate (e.g., a hydrogen), resulting in forming adsorption sites (i.e., OH— group) thereon. In other words, the oxygen source may be supplied to form adsorption sites on the surface of the silicon oxide film. FIGS. 2A to 2D may be repeated until the target film thickness is achieved.

In one embodiment of FIG. 1 and FIGS. 2A to 2D, a growth rate of the silicon oxide film on the substrate may be about 0.5 Å/cycle or greater, or about 1.0 Å/cycle or greater.

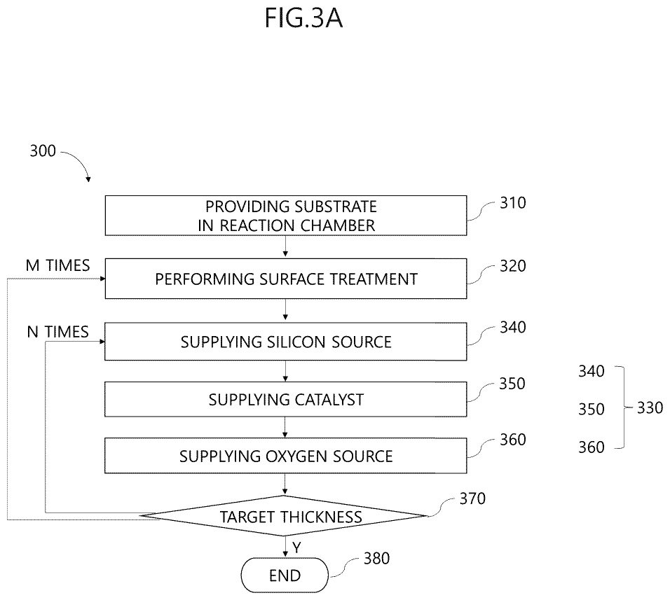

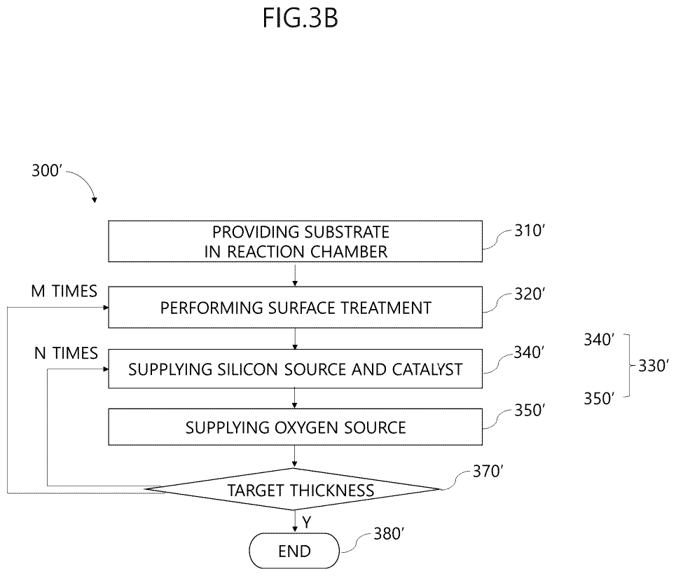

FIGS. 3A to 3B illustrate a method 300 of forming a film according to another embodiment of the disclosure.

In a STEP 310 of the method 300 in FIG. 3A, a substrate may be provided in a reaction chamber. The substrate may comprise a non-planar structure. For instance, the non-planar structure may comprise one or more of a recess, a trench, a gap, a via, a hole, a pattern and a 3D structure. The substrate provided in the reaction chamber may be loaded onto a substrate holder installed in the reactor (not shown herein). The substrate holder may comprise a susceptor and a heating block to heat up the substrate to a process temperature.

In a STEP 320 of the method 300 of FIG. 3, a surface treatment may be performed.

In the STEP 320, the surface treatment to the substrate may be performed by supplying a treatment gas to the substrate while applying a second power to the reaction chamber from the power generator before forming the film. The STEP 320 may be repeated at least one time.

In the STEP 320, the second power may be at least one of a low frequency power and a high frequency power. In one embodiment, the second power may be applied with a power of between about 30 W and about 1,500 W at a frequency of at least one of between about 300 kHz and about 1 MHz and between about 10 MHz and about 60 MHz.

The surface treatment may be performed for about 1 second or less, or for about 0.2 seconds or less while applying the second power to the reaction chamber.

The treatment gas may comprise a nitrogen and a hydrogen. For instance, the treatment gas may comprise at least one of a mixture of N₂ and H₂, NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

In a STEP 330 of the method 300 in FIG. 3, a film may be formed on the substrate. The film formed on the substrate may be a silicon oxide.

The STEP 330 may comprise a STEP 340 of supplying a silicon source, a STEP 350 of supplying a catalyst, a STEP 360 of supplying an oxygen gas. In one embodiment, the STEP 330 may be repeated until a target film thickness is achieved (i.e., N times). In another embodiment, the STEPS 320 and 330 may be repeated until a target film thickness is achieved (i.e., M times). In another embodiment, a super cycle comprising the STEP 320 and the STEP 330 may be repeated.

In a STEP 370, whether the target film thickness is achieved or not may be determined. In a STEP 380, after the film target thickness is achieved, the method of forming the film may end.

In STEP 340 and STEP 350, the silicon source and the catalyst may be supplied to form a silicon oxide film on the substrate. The silicon source and the catalyst may be supplied sequentially and alternately.

The catalyst may promote the silicon source to react with the surface of the substrate, resulting in adsorbing thereon. In more detail, the catalyst may assist the silicon source to react with adsorption sites (e.g., OH— group) formed on the surface of the substrate, resulting in promoting the silicon oxide film to be formed on the surface of the substrate. Since the silicon oxide film may be formed without supplying an oxygen source, the whole process time to form the silicon oxide film in the STEP 330 may be reduced.

In one embodiment of the disclosure, the silicon source may comprise an amine and the catalyst may comprise a nitrogen and a hydrogen.

The silicon source may comprise at least of one of trisilylamine ((SiH₃)₃N); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane (SiH₃N(iPr)₂); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄), or a mixture thereof.

The catalyst may comprise at least one of NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

In a STEP 360, an oxygen source may be supplied to the substrate. The oxygen source may react with the top surface of the silicon oxide film formed in STEPS 340 and 350, resulting in forming adsorption sites (e.g., OH— group) on the silicon oxide film. In one embodiment, the oxygen source may be supplied while applying a first power to the reaction chamber from a power generator.

The oxygen source activated by the first power may react with the top surface of the silicon oxide film more easily. The oxygen source may comprise at least one of O₂, O₃, H₂O, N₂O, CO₂, or a mixture thereof.

In the STEP 360, the first power may be at least one of a low frequency power and a high frequency power. In one embodiment, the first power may be applied with a power of between about 30 W and about 1,500 W at a frequency of at least one of between about 300 kHz and about 1 MHz and between about 10 MHz and about 60 MHz.

In one embodiment of the method 300, a cycle ratio of performing the substrate treatment to forming the film may be between 1:1 and 1:10.

In one embodiment of the method 300, the method may further comprise a super cycle repeating sub-steps of performing the substrate treatment 320 and forming the silicon oxide film 330 with a cycle ratio of between 1:1 and 1:10.

Optionally, the method 300 may further comprise supplying a purge gas (e.g., Ar) to the reaction chamber throughout the STEPS 320 and 330.

In one embodiment of the method 300, the STEPS 320 and 330 may be performed at between about 50° C. and about 600° C.

FIG. 3B illustrates another embodiment of the disclosure. In a STEP 320′ of a method 300′, a substrate treatment may be performed. The surface treatment to the substrate may be performed by supplying a treatment gas to the substrate while applying a second power to the reaction chamber from the power generator before forming the film. The STEP 320′ may be repeated at least one time.

In a STEP 340′, a silicon source and a catalyst may be supplied simultaneously. For instance, the catalyst may be supplied while supplying the silicon source. In a STEP 350′, an oxygen source may be supplied to the substrate. The oxygen source may react with the top surface of the silicon oxide film formed in the STEP 340′, resulting in forming adsorption sites (e.g., OH— group) on the silicon oxide film. In one embodiment, the oxygen source may be supplied while applying a first power to the reaction chamber from a power generator.

In one embodiment of the method 300′, the STEP 330′ may be repeated until a target film thickness is achieved (i.e., N times). In another embodiment, the STEPS 320′ and 330′ may be repeated until a target film thickness is achieved (i.e., M times). In another embodiment, a super cycle comprising the STEP 320′ and the STEP 330′ may be repeated.

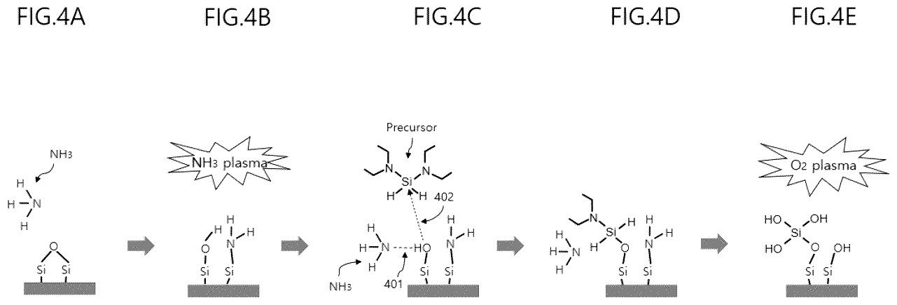

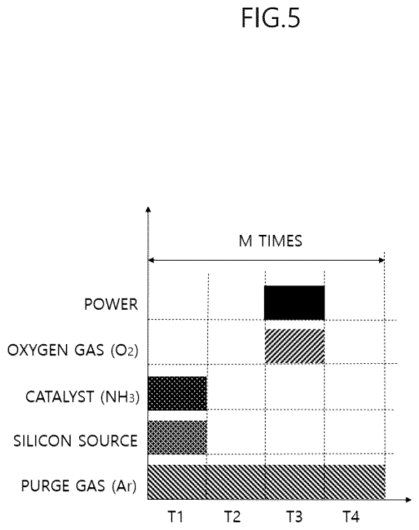

FIGS. 4A to 4E illustrate a reaction mechanism according to one embodiment of FIG. 3B.

In FIGS. 4A to 4B, the surface treatment to the substrate may be performed by supplying a treatment gas to the substrate while applying a second power to the reaction chamber from the power generator before forming the film.

In FIG. 4A, a NH₃ gas may be supplied as a treatment gas to the substrate. In FIG. 4B, the NH₃ gas may be activated to form a NH₃ plasma. The activated species (e.g., NH₃⁺ radicals, NH₄⁺ ions etc.) of the treatment gas may react with a Si—O—Si species formed on the substrate, resulting in forming a Si—OH and a Si—NH₂ bonding structures, for instance. The ‘OH—’group may act as an adsorption site in the subsequent step.

In FIG. 4C, a silicon source and a catalyst may be supplied simultaneously to the adsorption sites (i.e., OH— group) formed in the previous step (i.e., FIG. 4B). The silicon source may comprise an amine (e.g., aminosilane) and the catalyst may comprise a nitrogen and a hydrogen (e.g., NH₃).

In FIG. 4C, the catalyst may assist the reaction between the silicon source and with the adsorption sites. The catalyst may have an unshared electron pair. In particular, the nitrogen of the catalyst may contain an unshared electron pair (i.e., two unshared electrons). The polarity of unshared electron pair may cause the hydrogen comprising the adsorption site to be gravitated to the nitrogen of the catalyst, resulting in detaching the hydrogen from the adsorption site (denoted as 401) while the oxygen may remain therein.

In this reaction, the catalyst may act as an electron donor, and therefore, may be referred to as a Lewis base. The remaining oxygen may bond with the silicon of the silicon source (denoted as 402), forming a Si—O—Si bonding structure as illustrated in FIG. 4D. Therefore, the catalyst may promote the reaction between the silicon source and the oxygen of the adsorption site.

As the bonding strength between the hydrogen and the oxygen comprising the OH— adsorption site may be weakened as illustrated in FIG. 4C, the hydrogen may be detached easily from the OH— adsorption site. Thus, the formation of Si—O—Si bonding structure on the substrate may be further facilitated.

In FIG. 4E, an oxygen source may be supplied to the substrate. The oxygen source may be supplied while applying a first power to the reaction chamber. Oxygen radicals may react with the surface of the substrate (e.g., a hydrogen), resulting in forming adsorption sites (i.e., OH— group) thereon. In other words, the oxygen source may be supplied to form adsorption sites on the surface of the silicon oxide film. FIGS. 4B to 4E may be repeated until the target film thickness is achieved. In another embodiment, a super cycle comprising sub steps FIG. 4A and FIGS. 4B to 4E may be repeated.

In one or more embodiment, a growth rate of the silicon oxide film on the substrate may be about 0.5 Å/cycle or greater, or about 1.0 Å/cycle or greater.

FIG. 5 illustrates a timing graph of a method according to an embodiment of FIG. 1B.

In a STEP T1 of FIG. 5, a silicon source and a catalyst may be supplied simultaneously. In one embodiment, the silicon source may be supplied, followed by supplying the catalyst alternately and sequentially.

In a STEP T3, an oxygen source may be supplied while applying a power (i.e., a first power). In one embodiment, the power may be applied to the reaction chamber in-situ or remotely or both.

Optionally, STEPS T2 and T4 may be further performed as purge steps after STEP T1 and after STEP T3 to remove a residual gas from the reaction chamber. STEPS T1 to T4 may be repeated at least one time (M≥1).

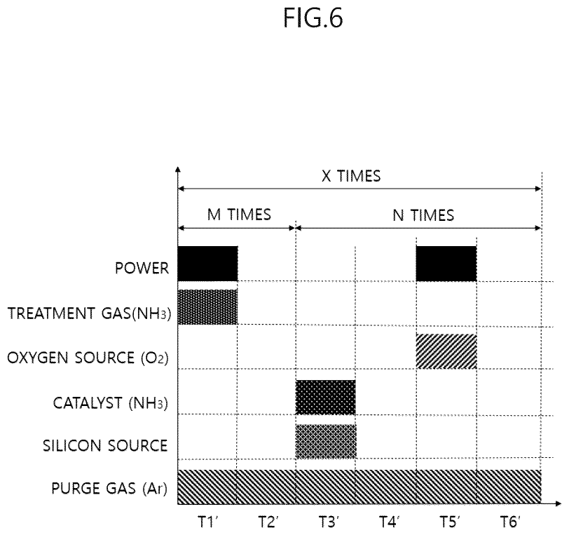

FIG. 6 illustrates a timing graph of a method according to another embodiment of FIG. 3B.

In a STEP T1′ of FIG. 6, a substrate treatment may be performed to the substrate. In the STEP T1′, a treatment gas may be supplied while applying a power (i.e., a second power). In one embodiment, the power may be applied in situ or remotely or both.

In a STEP T3′, a silicon source and a catalyst may be supplied simultaneously. In one embodiment, the silicon source may be supplied, followed by supplying the catalyst sequentially and alternately.

In a STEP T5′, an oxygen source may be supplied while applying the power (i.e., a first power) after the STEP T1′. In one embodiment, the power may be applied to the reaction chamber in-situ or remotely or both.

Optionally, STEPS T2′, T4′ and T6′ may be further performed as purge steps after STEP T1′, after STEP T3′, and after T6′ to remove a residual gas from the reaction chamber.

In FIG. 6, STEPS T1′ to T2′ may be performed at least one time (M≥1) and STEPS T3′ to T6′ may be performed at least one time (N≥1). The cycle ratio of M to N (M:N) may be between 1:1 and 1:10.

In FIG. 6, the method may further comprise a super cycle repeating sub-steps of the surface treatment step (i.e., STEPS T1′ to T2′) and the film formation step (i.e., STEPS T3′ to T6′) at least one time (X≥1).

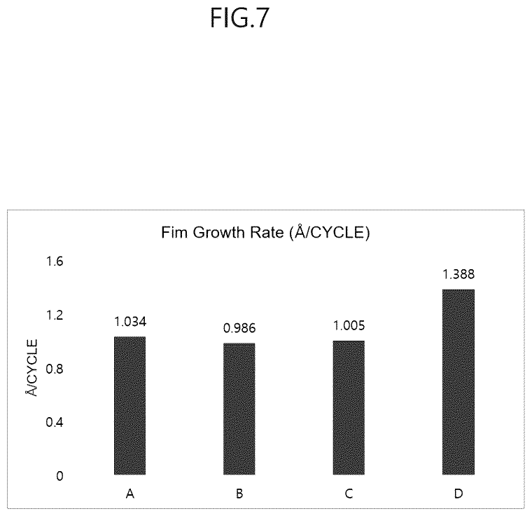

FIG. 7 illustrates a silicon oxide film growth rate depending on the catalyst and the surface treatment. Table 1 shows each film forming condition of FIG. 7

TABLE 1
Film forming conditions for forming a film according to FIG. 7

| | A | B | C | D |
|---|---|---|---|---|
| Surface treatment | Not done | Done | Not Done | Done |
| Supplying a catalyst | Not done | Not done | Done | Done |

In Condition A of Table 1, a surface treatment is not performed and a catalyst is not supplied. In Condition B, the surface treatment is performed, but the catalyst is not supplied. In Condition C, the surface treatment is not performed, but the catalyst is supplied. In Condition D, the surface treatment is performed and the catalyst is supplied.

In FIG. 7, when compared Conditions B and C with Condition A, the film growth rate of silicon oxide film is not significantly changed (i.e., about 1 Å/cycle) whether or not the surface treatment and the catalyst are used.

However, in Condition D in which both the surface treatment and supplying the catalyst are performed, the film growth rate is higher than other conditions.

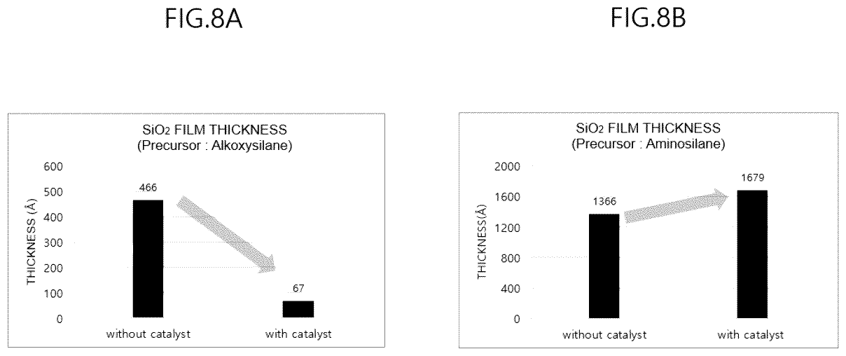

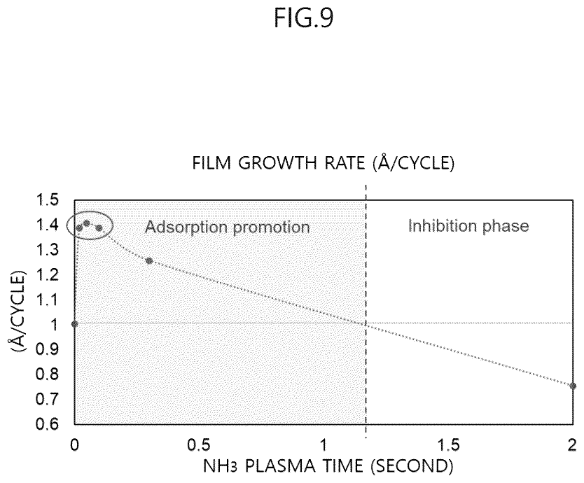

FIGS. 8A and 8B illustrates silicon oxide film thicknesses depending on the type of precursors and using the catalyst or not in which the film is formed without a surface treatment.

In FIG. 8A, the silicon oxide film is formed using a non-amine precursor alkoxysilane (e.g., 1,2-Bis(triethoxysilyl)ethane) at 200° C. When the silicon oxide film is formed without using a catalyst (e.g., NH₃), the thickness of the film is about 466 Å. In contrast, when the silicon oxide film is formed using a catalyst (e.g., NH₃), the thickness of the film is about 67 Å, reducing the thickness by 86%. In other words, the catalyst may act as an inhibitor when using a non-amine precursor, inhibiting the film from being formed.

In FIG. 8B, the silicon oxide film is formed using an amine precursor aminosilane (e.g., Bisdiethylaminosilane) at 200° C. When the silicon oxide film is formed without using a catalyst (e.g., NH₃), the thickness of the film is about 1,366 Å. In contrast, when the silicon oxide film is formed using a catalyst (e.g., NH₃), the thickness of the film is about 1,679 Å, increasing the thickness by 23%. In other words, the catalyst may promote the film to be formed when using an amine precursor.

FIG. 9 illustrates a film growth rate over the NH₃ plasma time in the substrate treatment step in which NH₃ may be supplied as a treatment gas.

In FIG. 9, when the NH₃ plasma time at the substrate treatment step is short, the formation of the silicon oxide film is promoted. In contrast, when the NH₃ plasma time is long, the formation of the silicon oxide film is inhibited. Therefore, the surface treatment may be performed for about 1 second or less while applying the power to the reaction chamber. More specifically, the surface treatment may be performed for about 0.2 seconds or less while applying the power to the reaction chamber.

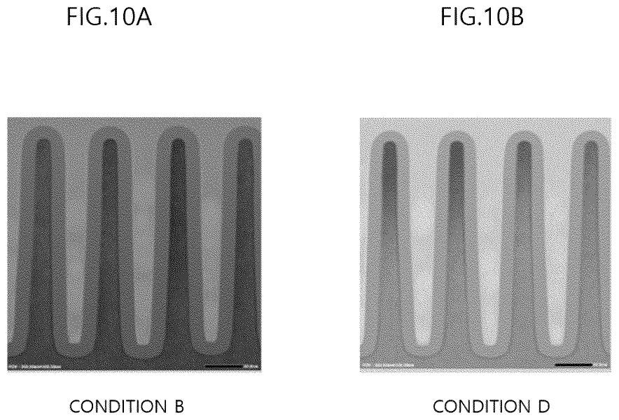

FIG. 10A and FIG. 10B are TEM (Transmission Electron Microscope) photos showing the silicon oxide film formed on the pattern according to an embodiment of the disclosure.

In FIG. 10A, the silicon oxide film may be formed according to Condition B of Table 1 in which the surface treatment is performed, but the catalyst is not supplied. In FIG. 10B, the silicon oxide film may be formed according to Condition D of Table 1 in which the surface treatment is performed and the catalyst is supplied. As shown in FIGS. 10A and 10B, the silicon oxide film may be formed conformally along the surface of the pattern to the lower portion of the pattern. Thus, a film may be formed conformally on the pattern by employing at least one of a surface treatment and a catalyst to form a film.

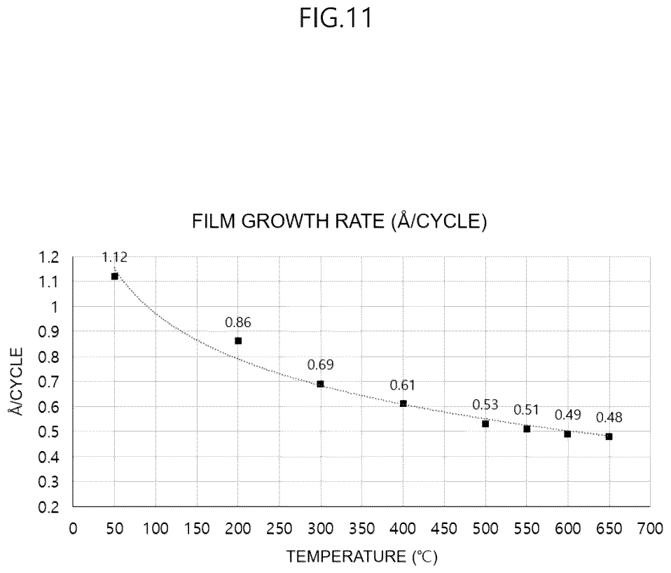

FIG. 11 illustrates a film growth rate of silicon oxide film over a process temperature according to an embodiment of the disclosure.

In FIG. 11, as the process temperature increases, the film growth rate of the silicon oxide film decreases due to thermal densification. According to the disclosure, a process may be required to be performed not to deliver a thermal shock to the reaction chamber and the substrate to be treated. Therefore, the process may not be performed at too high temperature.

In one embodiment of the disclosure, the process may be performed at between 50° C. and 600° C. As illustrated in FIG. 11, a film growth rate of the silicon oxide film may be about 0.5 Å/cycle or greater, or more specifically, about 1 Å/cycle or greater at between 50° C. and 600° C.

Table 2 shows test conditions for an embodiment of the disclosure.

TABLE 2
Test conditions for an embodiment of the disclosure

| Items | | Surface treatment | Deposition |
|---|---|---|---|
| Gas flow rate | Silicon source | — | 1,000 to 5,000, preferably 2,000 |
| (sccm) | carrier Ar | | to 4,000 |
| | NH₃ | 100 to 1,000, preferably | 100 to 1,000, preferably 300 to |
| | | 300 to 800 | 800 |
| | O₂ | — | 1,000 to 5,000, preferably 2,000 |
| | | | to 4,000 |
| | Purge Ar | 500 to 2,000, preferably | 1,000 to 5,000, preferably 2,000 |
| | | 800 to 1,500 | to 4,000 |
| Process time per | Silicon source | — | 0.5 to 3.0, preferably 1.0 to 2.0 |
| step (second) | feeding | | |
| | NH₃ feeding | 0.05 to 1.0, preferably 0.1 | 0.5 to 3.0, preferably 1.0 to 2.0 |
| | | to 0.5 | |
| | RF-ON | 0.05 to 1.0, preferably 0.1 | — |
| | | to 0.5 | |
| | Purge | 0.5 to 4.0, preferably 1.0 to | 0.5 to 4.0, preferably 1.0 to 2.0 |
| | | 2.0 | |
| | O₂ feeding/RF-ON | — | 1.0 to 10.0, preferably 3.0 to 8.0 |
| | Purge | — | 0.5 to 4.0, preferably 1.0 to 2.0 |
| Plasms condition | RF power (W) | 100 to 500 | 50 to 200 |
| | RF frequency | 10 to 60 | 10 to 60 |
| | (MHz) | | |

| | | |
|---|---|---|
| Pressure (Pa) | 300 to 500 | 400 to 800 |

| | |
|---|---|
| Temperature (° C.) | 50 to 600 |
| Silicon source | aminosilane |

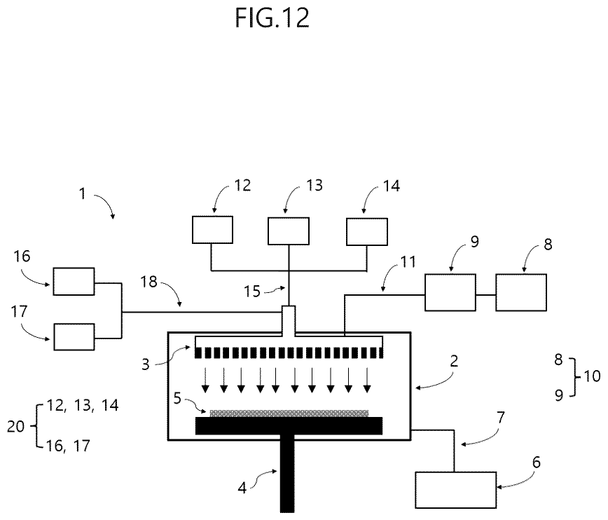

FIG. 12 illustrates one example of an apparatus for a substrate processing method according to the present disclosure.

In FIG. 12, the apparatus 1 may comprise a reaction chamber 2, a gas supply unit 3 to supply a gas into the reaction chamber 2, a substrate supporting unit 4 supporting a substrate 5 and is disposed facing the gas supply unit 3, an exhaust unit 6 to evacuate the reaction chamber 2, an exhaust path 7 connecting the reaction chamber 2 to the exhaust unit 60, and a power supply unit 10. The power supply unit 10 may comprise a power generator 8, a matching network 9 and a power delivery unit 11 to apply a power to the gas supply unit 3 from the power supply unit 10. The gas supply unit 3 may be a showerhead made of conductive material. The gas supply unit 3 may act as an electrode by being connected to the power supply unit 10 via the power delivery unit 11 to deliver a power to the reaction chamber 2.

The power generator 8 may generate at least one of a low frequency power (LRF) and a high frequency power (HRF). The matching network 9 may match an impedance between the power generator 8 and the reaction chamber 2. The power delivery unit 11 may deliver the power to the reaction chamber 2 from the power supply unit 10. The power delivery unit 11 may comprise a rod made of conductive material and a power deliver cable.

The apparatus 1 may further comprise a gas source unit 20 comprising a first gas source 12, a second gas source 13, a third gas source 14, a fourth gas source 16 and a fifth gas source 17.

The first gas source 12 may comprise a silicon source. The second gas source 13 may comprise an oxygen source as a reactant. The third gas source 14 may comprise an inert gas as a purge gas. The fourth gas source 16 may comprise a catalyst. The fifth gas source 17 may comprise a treatment gas.

The first gas source 12 may supply a first gas to the reaction chamber 2 via a gas supply path 15 and the gas supply unit 3. The second gas source 13 may supply a second gas to the reaction chamber 2 via the gas supply path 15. The third gas source 14 may supply a third gas to the reaction chamber 2 via the gas supply path 15.

The fourth gas source 16 may supply a fourth gas to the reaction chamber 2 via a gas supply path 18 and the gas supply unit 3. The fifth gas source 17 may supply a fifth gas to the reaction chamber 2 via the gas supply path 18.

In one or more embodiments, the substrate 5 may be processed in the reaction chamber 2 by the method comprising a surface treatment step to treat the surface of the substrate 5, followed by a film forming step to form a film on the substrate 5.

In the surface treatment step, a power may be applied to the reaction chamber 2 while supplying the treatment gas to the reaction chamber 2.

In the film forming step, the silicon source and the catalyst may be supplied to the reaction chamber 2, followed by applying the power to the reaction chamber 2 while supplying the oxygen source to the reaction chamber 2. The purge gas may be supplied to the reaction chamber 2 continuously throughout the surface treatment step and the film forming step.

What is claimed is:

1. A method of forming a film on a substrate, comprising:
providing the substrate in a reaction chamber; and
forming the film on the substrate by repeating a cycle at least one time, comprising:
supplying a silicon source comprising an amine to the substrate;
supplying a catalyst to the substrate; and
supplying an oxygen source to the substrate while applying a first power to the reaction chamber from a power generator, wherein the oxygen source reacts with the silicon source to form a silicon oxide film on the substrate.

2. The method of claim 1, wherein the catalyst is supplied while supplying the silicon source.

3. The method of claim 2, wherein the catalyst comprises a nitrogen and a hydrogen.

4. The method of claim 3, wherein the catalyst comprises at least one of NH₃, NH₄, N₂H₂, N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

5. The method of claim 1, wherein a growth rate of the silicon oxide film on the substrate is about 0.5 Å/cycle or greater.

6. The method of claim 5, wherein the growth rate of the silicon oxide film on the substrate is about 1.0 Å/cycle or greater.

7. The method of claim 1, further comprises performing a surface treatment to the substrate by supplying a treatment gas to the substrate while applying a second power to the reaction chamber from the power generator before forming the film, wherein performing the surface treatment is repeated at least one time.

8. The method of claim 7, the surface treatment is performed for about 1 second or less while applying the second power to the reaction chamber.

9. The method of claim 8, the surface treatment is performed for about 0.2 seconds or less while applying the second power to the reaction chamber.

10. The method of claim 7, wherein the treatment gas comprises a nitrogen and a hydrogen.

11. The method of claim 10, wherein the treatment gas comprises at least one of a mixture of N₂ and H₂, NH₃, NH₄, N₂H₂ and N₂H₄, (CH₃)₃CNH₂, (CH₃)₃CCH₂NH₂, (CH₃)₂CHNH₂, CH₃CH₂CH₂NH₂, CH₃CH₂NH₂, CH₃NH₂, C₂H₅NHC₂H₅, CH₃NHCH₃, (C₂H₅)₃N, (CH₃)₃N, C₇H₁₃N, C₁₀H₂₁NH₂, C₅H₅N, (CH₃)₂NC₅H₄N, (CH₃)₂NC₆H₅, CH₃NHC₆H₅, NH₂NH₂C₆H₅, (C₆H₅)₃N, (C₆H₅)NH(C₆H₅), or a mixture thereof.

12. The method of claim 1, wherein the silicon source is at least one of trisilylamine ((SiH₃)₃N); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane(SiH₃N(iPr)₂); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄), or a mixture thereof.

13. The method of claim 1, wherein the oxygen source comprises at least one of O₂, O₃, H₂O, N₂O, CO₂, or a mixture thereof.

14. The method of claim 1, wherein the first power is applied with a power of between about 30 W and about 1500 W at a frequency of at least one of between about 300 kHz and about 1 MHz and between about 10 MHz and about 60 MHz.

15. The method of claim 7, wherein the second power is applied with a power of between about 30 W and about 1500 W at a frequency of at least one of between about 300 kHz and about 1 MHz and between about 10 MHz and about 60 MHz.

16. The method of claim 7, wherein a cycle ratio of performing the surface treatment to forming the film is between 1:1 and 1:10.

17. The method of claim 16, wherein the method further comprises a super cycle repeating sub-steps comprising the method of claim 16 at least one time.

18. The method of claim 1, further comprises supplying a purge gas to the reaction chamber throughout performing the method of claim 1.

19. The method of claim 1, wherein the method of claim 1 is performed at between about 50° C. and about 600° C.

20. An apparatus performing the method of claim 1, comprising:
a reaction chamber;
a gas source unit;
a gas supply unit to supply a gas to the reaction chamber;
a substrate supporting unit to support a substrate and is disposed facing the gas supply unit; and
a power supply unit to apply a power to the reaction chamber,
wherein, the gas source unit comprises a silicon source, an oxygen source and a catalyst.
